(19) United States
(12) Patent Application Publication
(10) Pub. No.: US 2025/0037994 A1
(43) Pub. Date: Jan. 30, 2025

(54) METHODS OF FILLING TRENCHES ON SUBSTRATE SURFACE

(71) Applicant: ASM IP Holding B.V., Almere (NL)

(72) Inventors: Yoshio Susa, Tokyo (JP); Hirotsugu Sugiura, Tokyo (JP); Yoshiyuki Kikuchi, Tokyo (JP); Abhudaya Mishra, Chandler, AZ (US); Alexey Remnev, Kawasaki (JP)

(21) Appl. No.: 18/782,382

(22) Filed: Jul. 24, 2024

Related U.S. Application Data
(60) Provisional application No. 63/529,456, filed on Jul. 28, 2023.

(51) Int. Cl. H01L 21/02; H01J 37/32

(52) U.S. Cl. CPC H01L 21/02274; H01J 37/32449; H01L 21/02115; H01J 37/32082; H01J 2237/332; H01J 2237/334

(57) ABSTRACT

A method of filling trenches on a surface of a substrate is provided. The method may comprise the steps of: positioning a substrate on a substrate support, the substrate support disposed within a reaction chamber, wherein a pressure of the reaction chamber is less than 200 Pa; flowing a carbon precursor into the reaction chamber continuously; flowing an etching gas into the reaction chamber continuously; generating a plasma in the reaction chamber by applying a first radio frequency (RF) power to one of one or more electrodes of the reaction chamber; and depositing an amorphous carbon layer in the trenches on the substrate.

### CROSS-REFERENCE TO RELATED APPLICATIONS

This application claims priority to U.S. Provisional Patent Application Ser. No. 63/529,456 filed Jul. 28, 2023 titled METHODS OF FILLING TRENCHES ON SUBSTRATE SURFACE, the disclosure of which is hereby incorporated by reference in its entirety.

### FIELD OF INVENTION

The present disclosure generally relates to methods of forming structures suitable for use in the manufacture of electronic devices. More particularly, examples of the disclosure relate to methods of forming structures including depositing a material layer that may fill trenches on a surface of the structure.

### BACKGROUND OF THE DISCLOSURE

During the manufacture of devices, such as semiconductor devices, it is often desirable to fill trenches on the surface of a substrate. Some techniques to fill trenches include the deposition of a layer of flowable material, such as a flowable carbon material.

Although use of flowable carbon material to fill trenches may work well for some applications, deposition techniques of flowable carbon may have low elastic modulus and require a curing step. Accordingly, improved methods of filling trenches on a substrate surface with material having a high elastic modulus without requiring a curing step, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of filling trenches on a substrate is provided. The method may comprise the steps of: positioning a substrate on a substrate support, the substrate support disposed within a reaction chamber, wherein a pressure of the reaction chamber is less than 200 Pa; flowing a carbon precursor into the reaction chamber continuously; flowing an etching gas into the reaction chamber continuously; generating a plasma in the reaction chamber by applying a first radio frequency (RF) power to one of one or more electrodes of the reaction chamber; and depositing an amorphous carbon layer in the trenches on the substrate.

In various embodiments, the substrate support may be maintained at a temperature between about 350° C. and about 550° C.

In various embodiments, the first RF Power may be applied continuously.

In various embodiments, the first RF power may be less than 2000 W.

In various embodiments, a frequency of the first RF may be between 10 and 30 MHz.

In various embodiments, a second RF power may be applied to one of one or more electrodes of the reaction chamber.

In various embodiments, the second RF power may be less than 500 W.

In various embodiments, a frequency of the second RF may be between 100 KHz and 1000 KHz

In various embodiments, the flow rate of the carbon precursor may be between 10 and 200 sccm.

In various embodiments, the carbon precursor may comprise one of CH4, C2H2, C3H8, C4H10, C2H4, C3H6, C4H8, C5H10, C9H12, C6H11N3, C10H12O2, or a combination thereof.

In various embodiments, the etching gas may comprise one of H2, He, O2, CO2, NH3, N2O, or a combination thereof.

In various embodiments, the flow rate of the etching gas may be between 5 and 200 sccm.

In various embodiments, one of the electrodes may be part of the substrate support.

In various embodiments, an elastic modulus of the amorphous carbon layer may be more than 20 GPa.

### BRIEF DESCRIPTION OF THE DRAWING FIGURES

A more complete understanding of exemplary embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure formed in in a prior art reference.

FIG. 3 illustrates a schematic image of structures in accordance with exemplary embodiments of the disclosure.

FIG. 4 illustrates a plasma system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that may excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

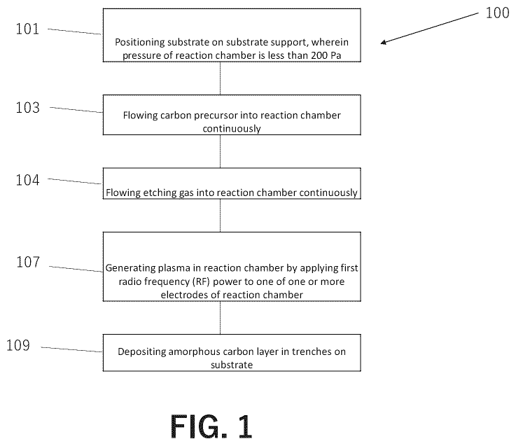

FIG. 1 illustrates a method 100 of filling trenches on a surface of a substrate in accordance with exemplary embodiments of the disclosure. Method 100 may include steps of positioning a substrate on a substrate support, the substrate support disposed within a reaction chamber (step 101); wherein a pressure of the reaction chamber is less than 200 Pa; flowing a carbon precursor into the reaction chamber continuously (step 103); flowing an etching gas into the reaction chamber continuously (step 104); generating a plasma in the reaction chamber by applying a first radio frequency (RF) power to one of one or more electrodes of the reaction chamber (107); and depositing an amorphous carbon layer in the trenches on the substrate (step 109).

During step 101 of providing a substrate on a substrate support within a reaction chamber, the substrate may be provided into a reaction chamber of a gas-phase reactor. In accordance with examples of the disclosure, the reaction chamber may form part of a deposition reactor, such as a plasma enhanced chemical vapor deposition (PECVD) reactor. Various steps of methods described herein may be performed (e.g., continuously) within a single reaction chamber or may be performed in multiple reaction chambers, such as reaction chambers on a cluster tool.

During step 101, the substrate may be brought to a desired temperature and/or the reaction chamber may be brought to a desired pressure, such as a temperature and/or pressure suitable for subsequent steps. By way of examples, a temperature (e.g., of a substrate or a substrate support) within a reaction chamber may range between about 350° C. to about 550° C. A pressure within the reaction chamber may be maintained less than 200 Pa. In accordance with particular examples of the disclosure, the substrate includes one or more features, such as narrow trenches and wide trenches.

During step 103, the carbon precursor may be flowed onto a surface of a substrate. The carbon precursor to fill the trenches may be flowed during step 103. The flow rate of the carbon precursor is between 10 and 200 sccm. The carbon precursor may comprise one of CH4, C2H2, C3H8, C4H10, C2H4, C3H6, C4H8, C5H10, C9H12, C6H11N3, C10H12O2, or a combination thereof. During steps 103, one or more inert gases, carrier gas, and dilution gas such as argon, helium, nitrogen, or any mixture thereof, may be provided to the reaction chamber.

During step 104, the etching gas may be supplied to the reaction chamber continuously. Steps 104 and 103 may be overlapped. The ratio of the etching to the deposition may be substantially equal. The etching gas may comprise one of H2, He, O2, CO2, NH3, N2O, or a combination thereof. The flow rate of the etching may range from about 5 to about 200 sccm.

During step 107, a plasma may be generated in the reaction chamber by applying a first radio frequency (RF) power to one of one or more electrodes of the reaction chamber. The plasma power ranges for deposition may range from about 10 W to about 2,000 W. An RF frequency of the plasma power may range from 400 kHz to 100 MHz. In some embodiments, the frequency may be between 10 MHz and 30 MHz. In some embodiments, a second RF power may be applied to one of one or more electrodes of the reaction chamber. A frequency of the second RF may be between 100 KHz and 1000 KHz and the second RF power may be less than 500 W.

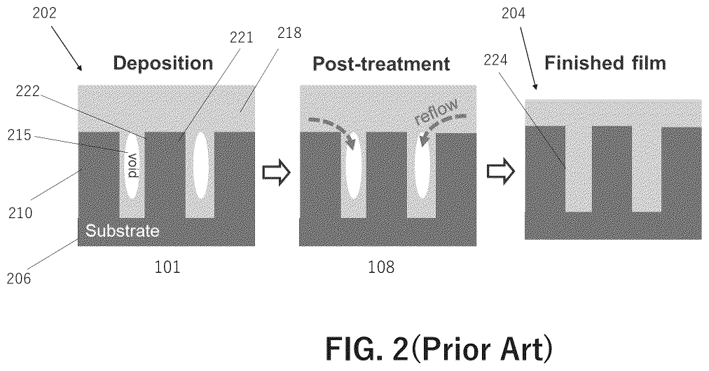

FIG. 2 illustrates a structure formed in in a prior art reference. Structure 202 may include a substrate 206 and protrusions 210, 221 formed thereon. Structure 202 includes deposited material 218 overlying substrate 206. As illustrated, deposited material 218 from deposition step 101 includes a void 215 formed within a trench 222 between protrusions 210 and 221. After material 218 is deposited (e.g., enough material to fill the trench 222), deposited material 218 may be exposed to a curing (post-treatment) step to cause deposited material 218 to flow within trench 222 to form structure 204, which includes treated material 224.

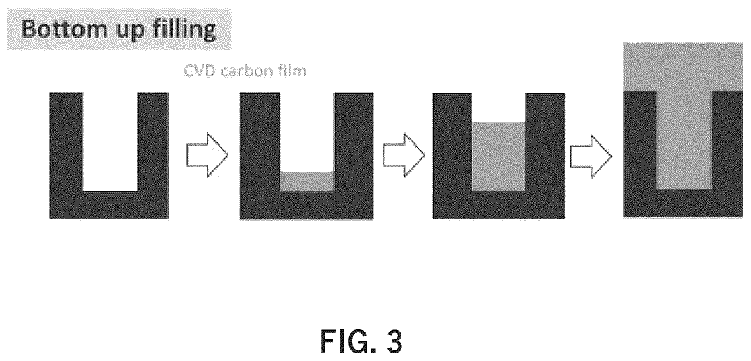

FIG. 3 illustrates a schematic image of structures in accordance with exemplary embodiments of the disclosure. The carbon precursor and the etching gas may be supplied to the reaction chamber simultaneously. By conducting the deposition and etching at the same time, an amorphous carbon bottom-up fill may be achieved. An elastic modulus of the amorphous carbon layer may be more than 20 GPa.

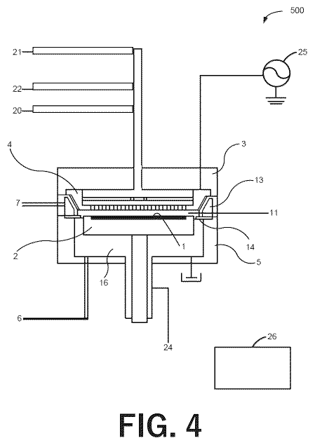

FIG. 4 illustrates a plasma reactor system 500 in accordance with exemplary embodiments of the disclosure is illustrated. The plasma reactor system 500 may be used to perform one or more steps or sub-steps as described herein and/or to form one or more structures or portions thereof as described herein.

The plasma reactor system 500 may include a pair of electrically conductive flat-plate top and bottom electrodes 4, 2 in parallel and facing each other in an interior 11 (reaction zone) of a reaction chamber 3. A plasma may be excited within the reaction chamber 3 by applying, for example, RF power (e.g., 13.56 MHz, 27 MHz, or 60 MHz) and/or low frequency power from a power source 25 to one electrode (e.g., the top electrode 4) and electrically grounding the other electrode (e.g., the bottom electrode 2). A temperature regulator may be provided in the bottom electrode 2 (serving as a substrate support 2), and a temperature of a substrate 1 placed thereon may be kept at a desired temperature. The top electrode 4 may serve as a gas distribution device, such as a shower plate. Reactant gas, carrier gas, inert gas, dilution gas, if any, precursor gas, and/or the like may be introduced into reaction chamber 3 using one or more of a gas line 20, a gas line 21, and a gas line 22, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6.

A skilled artisan will appreciate that the apparatus includes one or more controller(s) programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) may be used, wherein a reactant gas and a noble gas may be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of filling trenches on a substrate, comprising the steps of:
positioning a substrate on a substrate support, the substrate support disposed within a reaction chamber, wherein a pressure of the reaction chamber is less than 200 Pa;
flowing a carbon precursor into the reaction chamber continuously;
flowing an etching gas into the reaction chamber continuously;
generating a plasma in the reaction chamber by applying a first radio frequency (RF) power to one of one or more electrodes of the reaction chamber; and
depositing an amorphous carbon layer in the trenches on the substrate.

2. The method of claim 1, wherein the substrate support is maintained at a temperature between about 350° C. and about 550° C.

3. The method of claim 1, wherein the first RF Power is applied continuously.

4. The method of claim 1, wherein the first RF power is less than 2000 W.

5. The method of claim 1, wherein a frequency of the first RF is between 10 MHz and 30 MHz.

6. The method of claim 1, wherein a second RF power is applied to one of one or more electrodes of the reaction chamber.

7. The method of claim 6, wherein the second RF power is less than 500 W.

8. The method of claim 5, wherein a frequency of the second RF is between 100 KHz and 1000 KHz.

9. The method of claim 1, wherein a flow rate of the carbon precursor is between 10 and 200 sccm.

10. The method of claim 1, the carbon precursor comprises one of CH4, C2H2, C3H8, C4H10, C2H4, C3H6, C4H8, C5H10, C9H12, C6H11N3, C10H12O2, or a combination thereof.

11. The method of claim 1, the etching gas comprises one of H2, He, O2, CO2, NH3, N2O, or a combination thereof.

12. The method of claim 11, wherein a flow rate of the etching gas is between 5 and 200 sccm.

13. The method of claim 1, wherein one of the electrodes is part of the substrate support.

14. The method of claim 1, wherein an elastic modulus of the amorphous carbon layer is more than 20 GPa.
